(19) United States
(12) Patent Application Publication
(10) Pub. No.: US 2010/0243021 A1
(43) Pub. Date: Sep. 30, 2010

(54) Solar cells and methods for manufacturing the same

(75) Inventors: Jong Woo Lee, Suwon-si (KR); Eun Soo Hwang, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/659,646

(22) Filed: Mar. 16, 2010

(30) Foreign Application Priority Data
Mar. 26, 2009 (KR) 10-2009-0025742

(51) Int. Cl. H01L 31/042; H01L 31/18

(52) U.S. Cl. 136/244; 438/73; 257/E31.124

(57) ABSTRACT

Solar cells and methods of manufacturing the same are provided, the solar cell include a plurality of unit cells connected to one another on the same level of a substrate to form a module, each of the unit cells including a first electrode and a second electrode having opposite polarities and an active layer interposed between the first electrode and the second electrode.

### CROSS-REFERENCE TO RELATED APPLICATION(S)

This application claims the benefit of priority under 35 U.S.C. §119 from Korean Patent Application No. 10-2009-0025742, filed on Mar. 26, 2009 in the Korean Intellectual Property Office, the disclosure of which is incorporated herein by reference.

### BACKGROUND

1. Field

Example embodiments relate to solar cells wherein unit cells are aligned in series and parallel and thus modulated on a substrate, and methods for manufacturing the same.

2. Description of the Related Art

In accordance with a recent increase in demand for alternative energy in response to the exhaustion of fossil fuels and environmental problems, solar photovoltatic power generation, as a representative source of renewable energy, is becoming increasingly important. Solar photovoltatic power generation focuses on the development of solar cells, and techniques associated with solar cells have been under development for several decades.

Solar cells generate electrical energy using solar energy, are environmentally-friendly, tap (or use) a nearly infinite energy source and have a substantially long life span. Solar cells include crystalline silicon solar cells made of crystalline silicon (e.g., mono-crystalline silicon or poly-crystalline silicon), amorphous silicon solar cells, compound semiconductor solar cells made of Group IV compounds (e.g., amorphous SiC, SiN, SiGe or SiSn), Group III-V compounds (e.g., gallium arsenide (GaAs), aluminum gallium arsenide (AIGaAs), indium phosphide (InP)), or Group II-VI compounds (e.g., CdS, CdTe, or Cu₂S), and dye sensitized solar cells (DSSCs) including semiconductor nano-particles containing titanium dioxide (TiO₂) as a main component, dyes, electrolytes and transparent electrodes, etc.

For practical application of solar cells, an increase in photoelectric conversion efficiency to secure desired electromotive force (EMF) and realization of a large area of solar cells are desirable. The larger the width of a solar cell, the longer the electron movement distance. In this regard, because an electrode used for solar cells is made of a transparent electrode having a substantially high resistance for transmission of external light, large areas of solar cells do not have substantially high photoelectric conversion efficiency (as opposed to small areas of solar cells). Specifically, large areas of solar cells have substantially low photoelectric conversion efficiency because electrons formed by external light move far through a high-resistance transparent electrode.

One method for increasing the photoelectric conversion efficiency of large-area solar cells is to realize a module including a plurality of unit cells, each serving (or functioning) as one solar cell, connected in a series/parallel arrangement. Amorphous silicon solar cells, or compound semiconductor solar cells, have a structure in which transparent electrodes, semiconductor electrodes and metal electrodes are sequentially deposited, transcribed several times and then connected to one another in a series arrangement. Dye sensitized solar cells may be used to realize (or form) a unit cell module including a plurality of unit cells by manufacturing the unit cells and serially arranging the same with a conductive tape.

In the process of this modulation, the connection areas of unit cells cannot practically convert solar energy (i.e., light energy) into electric energy (photoelectrical conversion), thus decreasing an active area and making it impossible (or difficult) to obtain the photoelectric conversion efficiency needed to secure desired electromotive force due to contact problems between unit cells and electrodes. Thus, the unit cell module may exhibit electrical non-uniformity and/or increased solar cell module defects due to physical non-uniformity.

### SUMMARY

Example embodiments relate to solar cells wherein unit cells are aligned in series and parallel and thus modulated on a substrate, and methods for manufacturing the same.

In accordance with example embodiments, a solar cell includes a plurality of unit cells connected to one another on the same level (or height) of a substrate to form a module, each of the unit cells including a first electrode and a second electrode having different polarities, and an active layer interposed between the first electrode and the second electrode.

The first electrodes and the second electrodes of the unit cells may be alternately arranged on the substrate, wherein the unit cells are connected in series on the same level (or height) of the substrate. The first electrodes and the second electrodes of the unit cells may be randomly arranged on the substrate, wherein the unit cells are connected in parallel on the same level (or height) of the substrate. The first electrodes and the second electrodes of a part of the unit cells may be alternately arranged on the substrate, and the first electrodes and the second electrodes of the remaining unit cells may be randomly arranged on the substrate, wherein the unit cells are connected in series and parallel on the same level (or height).

The adjacent unit cells may be spaced by a gap of a set size, and the solar cell further includes a line connecting the unit cells printed in the gap.

The first electrode and the second electrode may be printed using an ink-jet method.

The active layer may be formed of a p-type, i-type or n-type material. The active layer may be made of a blend of an electron-donor and an electron-acceptor. The electron-donor and the electron-acceptor may form a bi-layer structure. The blend of the electron-donor and the electron-acceptor may be phase-separated.

The solar cell may include a self-assembled monolayer to phase-separate the blend. The self-assembled monolayer may have a submicron or nanometer-scale pattern.

In accordance with example embodiments, a method for manufacturing a solar cell includes forming a first electrode layer having a plurality of electrodes on a substrate, forming an active layer on the electrodes, forming a second electrode layer having a plurality of electrodes on the active layer to form a plurality of unit cells, and connecting the unit cells on the same level and modulating the same.

The first electrode layer and the second electrode layer each include a plurality of first electrodes and a plurality of second electrodes having opposite polarity than the first electrodes.

The electrodes of the second electrode layer may be formed (or arranged) such that each electrode formed on the active layer corresponds to an electrode of the first electrode layer formed on the substrate (and under the active layer). The corresponding two electrodes may have different (or opposite) polarities. The electrodes may be formed using an ink-jet printing method.

The formation of electrodes in the first and second electrode layers may include alternately forming the plurality of first electrodes and the plurality of second electrodes such that the first and second electrodes of each electrode layer are spaced from each other by a gap of a set size, and printing a line in the gap to connect the unit cells to each other in series.

The formation of the electrodes on the substrate may include forming a plurality of electrodes having the same polarity such that the electrodes are spaced from each other by a gap of a set size, and printing a line in the gap to connect the unit cells to each other in parallel.

The formation of the active layer may include coating a self-assembled monolayer on the electrodes formed on the substrate, providing a blend of an electron-donor and an electron-acceptor, and phase-separating the blend. The self-assembled monolayer may be coated using micro contact printing.

In accordance with example embodiments, a solar cell includes a plurality of unit cells, each of the unit cells including a first electrode and a second electrode having different polarities, and an active layer interposed between the first and second electrodes and formed of an electron-donor and an electron-acceptor that are phase-separated.

The solar cell may include a self-assembled monolayer to phase-separate the electron-donor from the electron-acceptor. The self-assembled monolayer may have a submicron or nanometer scale pattern.

In accordance with example embodiments, a method for manufacturing a solar cell includes surface-treating a-first electrode with a self-assembled monolayer, providing a blend of an electron-donor and an electron-acceptor to the first electrode to form an active layer, and curing the blend to form a second electrode. The surface-treatment may be carried out using micro contact printing.

The formation of the active layer may include spin-coating, or printing, the blend to phase-separate the same.

### BRIEF DESCRIPTION OF THE DRAWINGS

These and/or example embodiments will become apparent and more readily appreciated from the following description of the embodiments, taken in conjunction with the accompanying drawings of which:

FIG. 1 is a view illustrating a solar cell comprising unit cells connected in series according to example embodiments;

FIG. 2 is a sectional view illustrating the solar cell according to example embodiments;

FIG. 3 a view illustrating an example of a solar cell including unit cells connected in series/parallel according to example embodiments;

FIGS. 4A-4D are a flow diagram illustrating cross-sectional views of a method for manufacturing a solar cell including a phase-separated active layer according to example embodiments;

FIGS. 5A-5C are a flow diagram illustrating a method of transcribing a self-assembled monolayer (SAM) material on a unit cell and spin-coating an electron-donor/acceptor blend on the unit cell having the SAM material according to example embodiments;

FIGS. 6A-6C are a flow diagram illustrating a method of transcribing an SAM material on the unit cell shown in FIGS. 5A-5C; and

FIG. 7 is a sectional view illustrating an active layer of the solar cell according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In order to more specifically describe example embodiments, various aspects will be described in detail with reference to the attached drawings. However, the present invention is not limited to example embodiments described.

Example embodiments relate to solar cells wherein unit cells are aligned in series and parallel and thus modulated on a substrate, and methods for manufacturing the same.

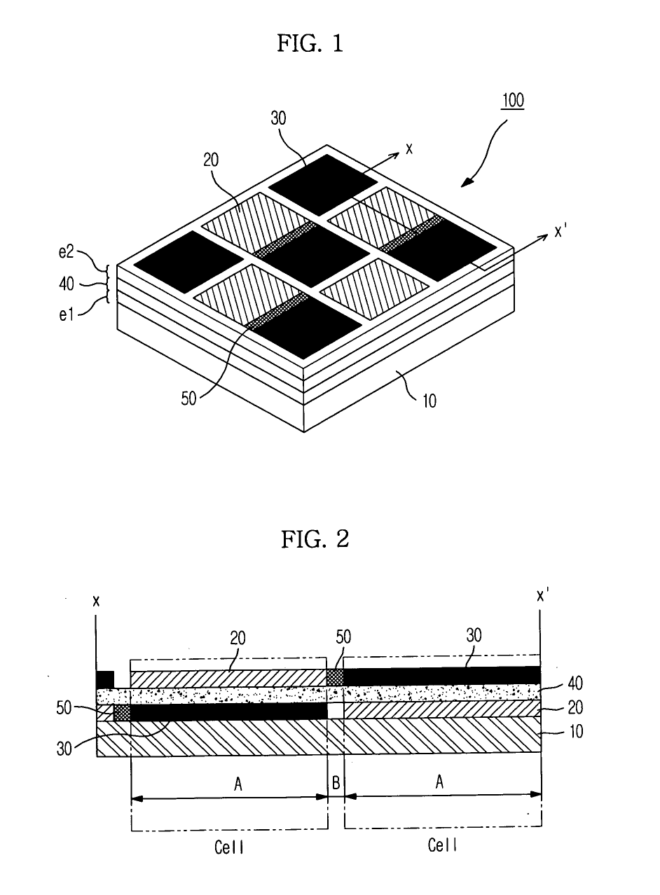

FIG. 1 is a view illustrating an example of a solar cell according to example embodiments. FIG. 2 is a sectional view taken along the line X-X′ of the solar cell of FIG. 1.

Referring to FIGS. 1 and 2, a solar cell 100 includes a plurality of unit cells, each including a substrate 10, a first electrode 20, a second electrode 30, an active layer 40 and a line 50 to connect the unit cells to each other.

The substrate 10 is a glass substrate, or a plastic substrate, used for low-temperature processes. For example, the substrate 10 may be formed of polyethylene terephthalate (PET) resins, polyethylene naphthalate (PEN), polyether sulfone (PS) or polyimide (PI). The substrate 10 includes a unit cell module arranged on one side.

The unit cell is a minimum unit to generate electricity. The plurality of unit cells is connected to one another to form a module that generates electricity. The first electrode 20 of each unit cell has a different polarity than the second electrode 30 of the respective unit cell. The active layer 40 of each unit cell is interposed between the first electrode 20 and the second electrode 30. The first electrode 20 is made of a material having a work function of about 5 eV (electron volt) and the second electrode 30 is made of a material having a work function of 4 eV or less. That is, the first electrode 20 is a positive polarity transparent electrode having a work function higher than the second electrode 30. The second electrode 30 is a positive polarity transparent electrode having a work function lower than the first electrode 20.

The materials for the electrodes have both conductivity and light-transparency. For example, the first electrode 20 and the second electrode 30 may be formed of a transparent conductive oxide. The transparent conductive oxide transmits all (or substantially all) incident light to increase photoelectric conversion efficiency. Examples of a transparent conductive oxide include ITO indium tin oxide (ITO), fluorine-doped tin oxide (FTO), zinc oxide (ZnOₓ), tin oxide (SnO₂), titanium oxide (TiO₂) and combinations thereof.

Transparent conductive oxide particles may be dispersed in a dispersion medium to form a conductive ink. The dispersion medium may be an aqueous and/or organic solvent. The conductive ink may include carbon nanotubes (or graphene) and a metal. Examples of useful metals include silver (Ag), copper (Cu), gold (Au), titanium (Ti), tungsten (W), nickel (Ni), chromium (Cr), molybdenum (Mo), lead (Pb), palladium (Pd), platinum (Pt) and combinations thereof.

The first and second electrodes 20 and 30 may be alternately printed by an ink-jet method on the same level of the substrate 10. The first and second electrodes 20 and 30 are printed at a set size, and a gap between the first electrode 20 and the second electrode 30 is controlled within an ink-jet resolution. The first and second electrodes 20 and 30 on the same level of the substrate 10 form a first electrode layer (e1). The first and second electrodes 20 and 30 on the same level of the substrate 10 and under the active layer the active layer 40 form a first electrode layer (e1).

The gap between the first electrode 20 and the second electrode 30 may be formed by printing the lines 50 to connect adjacent unit cells in series. The material used to form the line 50 is electrically conductive, allowing the first electrode 20 and the second electrode 30 to be electrically connected to each other.

When series connection between adjacent unit cells is unnecessary, the gap between the first electrode 20 and the second electrode 30 is left empty. The first electrode 10, the second electrode 20 and the line 50 may be arranged by printing on the substrate 10 using an ink-jet method. As such, series connection of the two electrodes 20 and 30 between the adjacent unit cells may be realized on the same level of the substrate 10.

The active layer 40 may be formed by printing, or coating, the first electrode 20 and the second electrode 30, which are alternately formed on the substrate 10. The first electrode 20 and the second electrode 30 may be alternately printed by an ink-jet method on the same level of the active layer 40. The first electrode 20 and the second electrode 30 on the same level of the active layer 40 form a second electrode layer (e2). The first electrode 20 and the second electrode 30 on the upper surface of the active layer 40 form a second electrode layer (e2).

The polarity alignment of the two electrodes 20 and 30 alternately arranged on the active layer 40 is contrary (or opposite) to the polarity alignment of the two electrodes 20 and 30 alternately arranged under the active layer 40. That is, the electrodes arranged on the active layer 40, which correspond to the electrodes arranged under the active layer 40, have opposite polarities to the electrodes arranged under the active layer 40.

As mentioned above, the electrodes 20 and 30 that face each other at opposite sides (or opposing surfaces) of the active layer 40 constitute a unit cell, collectively, with the active layer 40. The unit cell is connected to another unit cell through the line 50.

The first and second electrodes 20 and 30 and the line 50 are printed by a low-cost ink-jet method to realize a module. As such, it is possible to secure higher economic efficiency due to lower manufacturing costs and to increase a solar cell market share (or production), making it easier to manufacture solar cells. It is also possible to (i) realize series connection of unit cells on the same level, (ii) considerably decrease a non-active area B due to series-connection of unit cells and (iii) manufacture thin-film solar cells with a wide active area A, thereby increasing an energy conversion efficiency of the solar cell.

In example embodiments, unit cells may connected to one another in series on the same level by alternatively printing the first and second electrodes 20 and 30 on the substrate 10 and the active layer 40, and printing the line 50 in a space provided therebetween. Alternatively, the unit cells may be connected in parallel on the same level of the substrate by printing the adjacent electrodes arranged on the substrate 10 and the active layer 40 with electrodes having the same polarity as the electrodes being printed, and printing the line 50 therebetween.

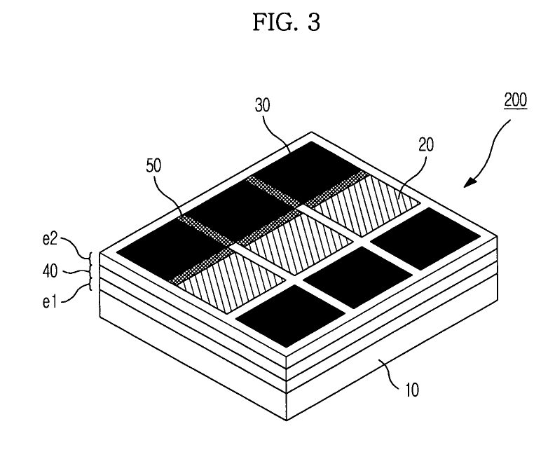

FIG. 3 a view illustrating an example of a solar cell including unit cells connected in series/parallel according to example embodiments.

Referring to FIG. 3, a solar cell 200 may include plurality of unit cells. The unit cells may be connected in series and parallel on the same level of a substrate 10 by suitably controlling polarity alignment of adjacent electrodes and printing a line 50. Because a first electrode 20 and a second electrode collectively with an active layer interposed therebetween form a unit cell, the first and second electrodes 20 and 30 arranged on and under the active layer 40 (the electrodes 20 and 30 facing each other at opposite sides (or opposing surfaces) of the active layer 40) have opposite polarities.

A more detailed explanation of the active layer 40 will be given below. The active layer 40 is adapted to form electron-hole pairs to allow electricity to flow through the first electrode 20 and the second electrode 30, when light is incident on the active layer 40. When light is incident on the active layer 40, an electron-donor absorbs the light to generate an excited state of electron-hole pairs or excitons. The electron-hole pairs diffuse in one direction, come in contact with an electron-acceptor on the interface therebetween, and the electron-hole pairs are then cleaved into electrons and holes. The electrons and holes move to respective electrodes due to an inner electric field generated by the difference in work function between the opposite electrodes, and the concentration difference between accumulated electric charges. At this time, the electrons move through the electron-acceptor to the second electrode 30, and the holes move through the electron-donor to the first electrode 20, allowing electricity to flow through an external circuit.

The active layer 40 may be formed by printing a p-type, i-type or n-type material suitable for use in solution processes, or by printing or coating a blend of an electron-donor and an electron-acceptor.

Examples of useful electron-acceptor materials for the active layer 40 include low-molecular weight compounds, conductive polymers, and substituted fullerenes (C₆₀) (e.g., [6.6]-phenyl C₆₁-butyric acid methyl ester (PCBM)), which are readily soluble in an organic solvent. Examples of electron-donor materials include poly para-phenylene vinylene (PPV) and polythiophene (PT) derivatives, monomers (e.g., phthalocyanine-based CuPc and ZnPc), and conductive polymers (e.g., poly(3-hexylthiophene) (P3HT)). Furthermore, electron-acceptor materials require substantially low light absorbance in a visible light area and substantially high affinity compared to electron-donor materials. Electron-donor materials require substantially light absorbance wavelengths comparable to solar light, or considerably high light absorbance.

The coating of the electron-donor/acceptor blend on the electrode is carried out by spin coating using a centrifugal force in a solution state, or by ink-jet-type printing.

The active layer 40 formed of the electron-donor/acceptor blend has a structure in which an electron-donor and an electron-acceptor form a bi-layer, or are phase-separated on a nanometer or submicron scale.

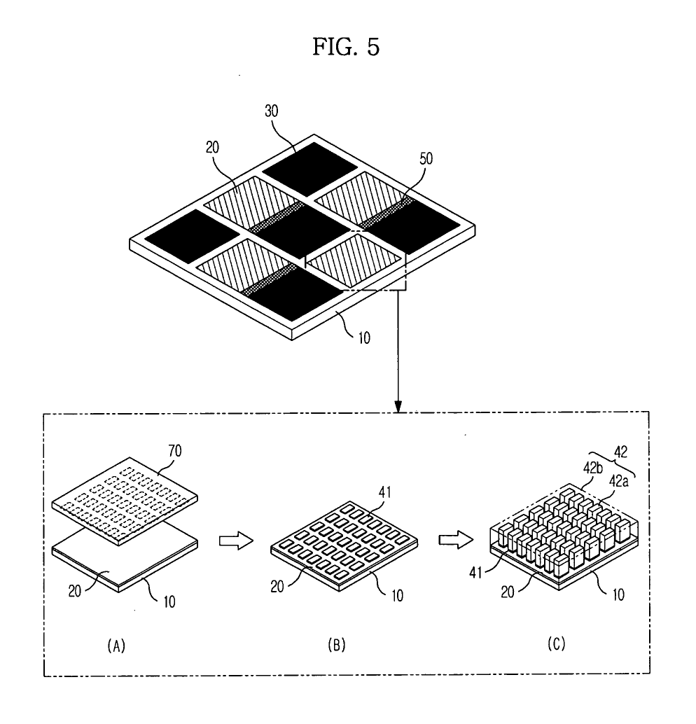

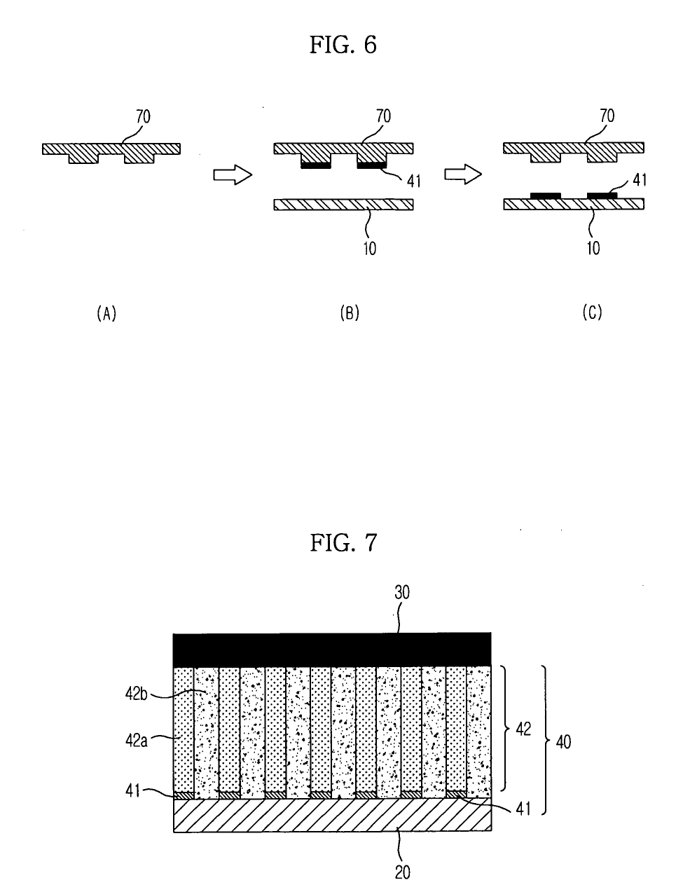

The phase-separation of the electron-donor and acceptor blend is obtained using micro contact printing capable of adjusting the surface energy on the surface of an electrode to a nanometer or submicron scale. The micro contact printing is a method in which a mold 70 (shown in FIGS. 5 and 6) with a set pattern is stained with a self-assembled monolayer (SAM) material and is then transcribed on an electrode.

When the phase-separated active layer 40 is formed, it is unnecessary to take the direction of the electron-donor/acceptor corresponding to the polarity of the electrode into consideration, making it easier to form an active layer 40. Also, more electrons are excited due to increased interface area, and photoelectric conversion efficiency is increased.

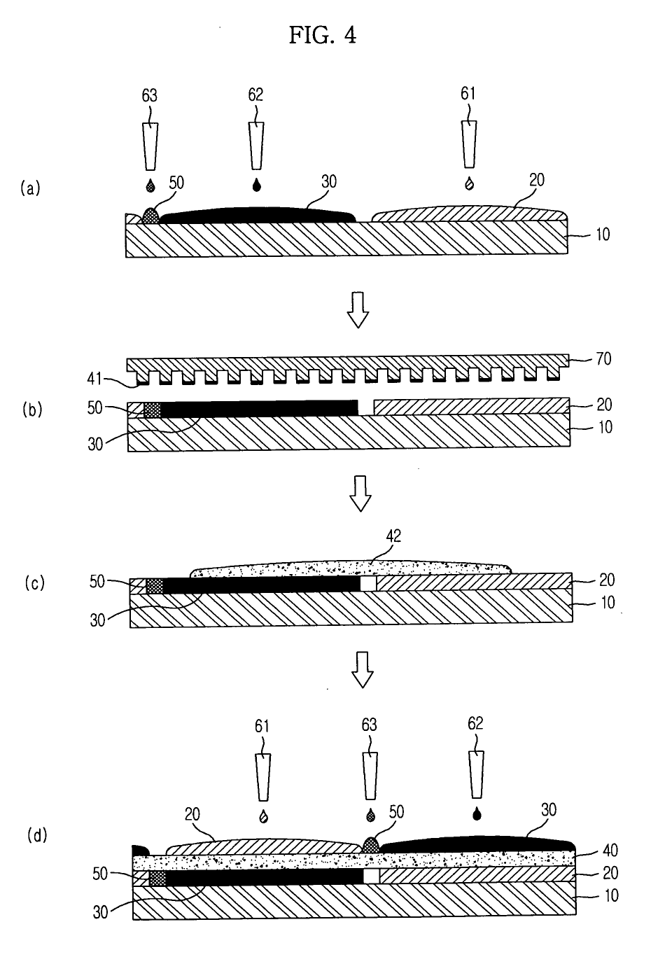

FIGS. 4 to 6 are a flow diagram illustrating a method for manufacturing a solar cell including a phase-separated active layer according to example embodiments. In the methods according to example embodiments, unit cells are modulated by a printing process to simplify a solar cell manufacturing process, low-cost and wide solar cells are realized, and formation of an electrode structure in the process of printing to reduce a non-active area (that does not contribute to energy conversion) is controlled. A process for manufacturing such a solar cell will be illustrated in detail.

FIGS. 4A-4D are a flow diagram illustrating cross-sectional views of a method for manufacturing a solar cell including a phase-separated active layer according to example embodiments.

Referring to FIG. 4A, a first electrode 20 is printed on the surface of a substrate 10 by ink-jetting. Ink-jetting is a method in which the substrate 10 is printed by discharging ink droplets containing a material for the first electrode 20 through an inkjet head 61 thereon.

Ink droplets printed on the substrate 10 are cured and a second electrode 30 is then printed on the surface of the substrate 10 in accordance with an ink-jet method. In the same manner as the printing of the first electrode 20, the second electrode 30 is printed by discharging ink droplets containing a material for the second electrode 30 through an inkjet head 62 thereon.

The second electrode material printed on the substrate 10 is cured and a line 50 is then printed on the surface of the substrate 10 in accordance with an ink-jet method. In the same manner as the printing of the first electrode 20, the line 50 is printed by discharging ink droplets containing a material for the line 50 through an inkjet head 63 thereon.

In the process of printing the first electrode 20, the second electrode 30 and the line 50, a droplet discharge time of the inkjet heads 61 to 63 is controlled to prevent mixing of ink droplets constituting the first electrode 20, the second electrode 30 and the line 50.

The first and second electrodes 20 and 30 are alternately printed on the same level of the surface of the substrate 10 in accordance with an ink-jet method. The first and second electrodes 20 and 30 are printed to a set size and the gap between the first electrode 20 and the second electrode 30 may be controlled within an inkjet definition.

The line 50 is printed in the gap between the first electrode 20 and the second electrode 30. The printed line 50 allows adjacent unit cells to be connected to each other in series. If a series connection between unit cells is necessary, the line 50 is printed in the gap between unit cells. If a series connection is not necessary, the gap between unit cells is left empty. Because the first electrode 10, the second electrode 20 and the line 30 are aligned by printing on one substrate 10 in accordance with an ink-jet method, a series connection of two electrodes 20 and 30 between adjacent unit cells is realized on the same level of the substrate 10.

A phase-separated active layer 40 is formed on the first electrode 20 and the second electrode 30 alternately arranged using micro contact printing capable of controlling the surface interface on the first and second electrodes 20 and 30 on a nanometer or submicron scale.

FIGS. 5A-5C are a flow diagram illustrating a method of transcribing a self-assembled monolayer (SAM) material on a unit cell and spin-coating an electron-donor/acceptor blend on the unit cell having the SAM material according to example embodiments. FIGS. 6A-6C are a flow diagram illustrating a method of transcribing an SAM material on the unit cell shown in FIGS. 5A-5C.

Referring to FIGS. 4B, 5A-5C and 6, a mold 70 for micro contact printing with a nanometer (or submicron) scale set pattern is stained with a material for a self-assembled monolayer (SAM) 41. The stained mold 70 contacts with the surface of the first electrode 20 and the second electrode 30. The SAM material 41 is transcribed with a set pattern to the surfaces of the first electrode 20 and the second electrode 30, allowing the two electrodes 20 and 30 to be surface-treated with the SAM material 41.

Referring FIGS. 5A-5C, the self-assembled monolayer (SAM) material 41 is transcribed on a unit cell and an electron-donor/acceptor blend 42 is spin-coated on to the unit cell having the SAM material 41.

Referring to FIGS. 6A-6C, the SAM material 41 is transcribed on the unit cell.

Referring to FIG. 4C, an electron-donor/acceptor acceptor 42 is printed, or spin-coated, by an ink-jet method on the surfaces of the first and second electrodes 20 and 30, on which the material for the SAM material 41 is transcribed.

FIG. 7 is a sectional view illustrating an active layer of the solar cell according to example embodiments.

Referring to FIGS. 5C and 7, when the electron-donor/acceptor blend 42 is printed, or spin-coated, on the surfaces of the SAM material-transcribed first and second electrodes 20 and 30, a hydrophobic material 42a (an electron-donor) is arranged on the surface of the first electrode 20, on which the material for the SAM 41 is printed, and a hydrophilic material 42b (an electron acceptor) is arranged on the two electrodes on which the material for the SAM 41 is not printed, to form a micro-scale phase-separation structure. The electron-donor 42a and the electron-acceptor 42b have different surface energies.

Referring to FIG. 7, an active layer 40 is formed on a unit cell.

After a material for the SAM 41 is printed with a mold 70 on the unit cell electrode and an electron-donor/acceptor blend 42 is then coated thereon and dried, the active layer 40 having a micro structure controlled in accordance with the SAM pattern is formed.

As shown in FIG. 4D, a first electrode 20 is formed by printing a material for the first electrode 20 on the active layer 40 in accordance with an ink-jet method, the printed first electrode 20 is cured, a second electrode 30 is formed by printing a material for the second electrode 30 in accordance with an ink-jet method, the second electrode 30 is cured, and a line 50 is formed by printing a material for the line 50 in accordance with an ink-jet method. At this time, the line 50 is printed between unit cells requiring series connection.

The two electrodes 20 and 30 printed on the active layer 40 are alternately arranged, while polarity alignment of the two electrodes 20 and 30 alternately printed on the active layer 40 is opposite to that of the two electrodes 20 and 30 arranged under the active layer 40.

The electrodes 20 and 30 (that face each other, while being arranged on and under the active layer 40) together with the active layer 40 constitute a unit cell, and the unit cell is electrically connected in series to another unit cell through the line 50, to form a module.

In example embodiments, unit cells are connected to one another in series on the same level of the substrate 10 by alternately printing the first and second electrodes 20 and 30 on the substrate 10 and the active layer 40, and then printing the line 50 in a space provided therebetween. The unit cells may be connected in parallel on the same level of the substrate 10 by printing the adjacent electrodes arranged on the substrate 10 and the active layer 40 with electrodes having the same polarity as the electrodes and printing the line 50 therebetween. The unit cells may be connected in series and parallel on the same level of the substrate by suitably controlling polarity alignment of adjacent electrodes and printing the line 50.

In example embodiments, a solar cell including a phase-separated active layer 40 was illustrated, but the active layer 40 may have a bi-layer structure including an electron-donor and an electron-acceptor. The solar cell including a bi-layer structure active layer 40 may be formed by printing an electron-donor material on a first electrode 10, printing an electron-acceptor material on the electron-donor material, and printing a second electrode 20 on the electron-acceptor material. The active layer 40 may be formed by printing a p-type, i-type or n-type material suitable for use in solution processes.

Although example embodiments have been shown and described, it would be appreciated by those skilled in the art that changes may be made in these embodiments without departing from the principles and spirit of the invention, the scope of which is defined in the claims and their equivalents.

What is claimed is:

1. A solar cell, comprising:
a plurality of unit cells connected to one another on a same level of a substrate to form a module, each of the unit cells including a first electrode and a second electrode having opposite polarities and an active layer between the first electrode and the second electrode.

2. The solar cell according to claim 1, wherein the first electrodes and the second electrodes of the plurality of unit cells are alternately arranged on the substrate, and the plurality unit cells are connected in series.

3. The solar cell according to claim 1, wherein the first electrodes and the second electrodes of the plurality of unit cells are randomly arranged on the substrate, and the plurality of unit cells are connected in parallel.

4. The solar cell according to claim 1, wherein the first electrodes and the second electrodes of a first group selected from among the plurality of unit cells are alternately arranged on the substrate,
the first electrodes and the second electrodes of a second group of the remaining unit cells are randomly arranged on the substrate, and
the plurality of unit cells are connected in series and parallel.

5. The solar cell according to claim 1, wherein adjacent unit cells are spaced apart by a gap of a set size, and the solar cell includes a line connecting the adjacent unit cells printed in the gap.

6. The solar cell according to claim 1, wherein the first electrode and the second electrode are printed using an ink-jet method.

7. The solar cell according to claim 6, wherein the active layer is made of a p-type, i-type or n-type material.

8. The solar cell according to claim 6, wherein the active layer is made of a blend of an electron-donor and an electron-acceptor.

9. The solar cell according to claim 8, wherein the electron-donor and the electron-acceptor form a bi-layer structure.

10. The solar cell according to claim 8, wherein the blend of the electron-donor and the electron-acceptor is phase-separated.

11. The solar cell according to claim 10, further comprising a self-assembled monolayer phase-separating the electron-donor from the electron-acceptor.

12. The solar cell according to claim 11, wherein the self-assembled monolayer has a submicron or nanometer-scale pattern.

13. A method for manufacturing a solar cell, comprising:
forming a first electrode layer having a plurality of electrodes on a substrate;
forming an active layer on the first electrode layer;
forming a second electrode layer having a plurality of electrodes on the active layer to form a plurality of unit cells;
connecting the plurality of unit cells on a same level of the substrate; and
modulating the connected unit cells.

14. The method according to claim 13, wherein forming the plurality of electrodes of the first electrode layer and the second electrode layer includes using an ink-jet printing method.

15. The method according to claim 13, wherein the first electrode layer and the second electrode layer each include a plurality of first electrodes and a plurality of second electrodes having an opposite polarity that the plurality of first electrodes, and
each of the plurality of electrodes of the second electrode layer corresponds to one of the plurality of electrodes of the first electrode layer, the corresponding electrodes of the first electrode layer and the second electrode layer having opposite polarities.

16. The method according to claim 15, wherein forming the plurality of electrodes of the first electrode layer and the second electrode layer includes:
alternately forming the plurality of first electrodes and the plurality of second electrodes such that the first and second electrodes of each electrode layer are spaced apart from each other by a gap of a set size; and
printing a line in the gap to connect the plurality unit cells to each other in series.

17. The method according to claim 15, wherein forming the plurality of electrodes of the first electrode layer includes:
spacing the plurality of first electrodes from each other by a gap of a set size, the plurality of first electrodes having the same polarity; and
printing a line in the gap to connect the plurality of unit cells to each other in parallel.

18. The method according to claim 13, wherein forming the active layer includes:
coating a self-assembled monolayer on the plurality of electrodes of the first electrode layer;
providing a blend of an electron-donor and an electron-acceptor; and
phase-separating the electron-donor from the electron-acceptor.

19. The method according to claim 18, wherein coating the self-assembled monolayer is performed using a micro contact printing method.

20. A solar cell, comprising:
a plurality of unit cells, each of the unit cells including a first electrode and a second electrode having different polarities; and
an active layer interposed between the first and second electrodes, the active layer being formed of an electron-donor and an electron-acceptor that are phase-separated.

21. The solar cell according to claim 20, further comprising:
a self-assembled monolayer phase-separating the electron-donor from the electron-acceptor.

22. The solar cell according to claim 21, wherein the self-assembled monolayer has a submicron or nanometer scale pattern.

23. A method for manufacturing a solar cell, comprising:
surface-treating a first electrode with a self-assembled monolayer;
providing a blend of an electron-donor and an electron-acceptor to the surface-treated first electrode to form an active layer; and
curing the blend of the electron-donor and the electron-acceptor to form a second electrode.

24. The method according to claim 23, wherein surface-treating the first electrode includes using a micro contact printing method.

25. The method according to claim 23, wherein forming the active layer includes spin-coating or printing the blend of the electron-donor and the electron-acceptor to phase-separate the electron-donor from the electron-acceptor.
